(19) United States
(12) Patent Application Publication
(10) Pub. No.: US 2025/0372472 A1
(43) Pub. Date: Dec. 4, 2025

(54) TOPSIDE COOLING BAND FOR MULTIPLE ELECTRONIC COMPONENTS

(71) Applicant: Texas Instruments Incorporated, Dallas, TX (US)

(72) Inventors: John Carlo Molina, Limay (PH); Rommel Rigo A. Magallanes, Baguio City (PH); Nicole Yabuuchi, Angeles (PH)

(21) Appl. No.: 18/676,814

(22) Filed: May 29, 2024

(51) Int. Cl. H01L 23/367; H01L 21/56; H01L 23/00; H01L 23/31; H01L 25/065

(52) U.S. Cl. CPC H01L 23/367; H01L 21/563; H01L 23/3107; H01L 24/16; H01L 25/0655; H01L 2224/16227

(57) ABSTRACT

An electronic device includes first and second electronic components having lateral sides, a first side attached to a substrate, and an opposite second side, a thermally conductive band having a bottom extending on the second sides of the first and second electronic components, a top, and sidewalls, the top, the bottom, and the sidewalls of the thermally conductive band defining an interior, and a package structure extending on the top side of the substrate, on the sidewalls and bottom of the thermally conductive band, and on the first side and the lateral sides of the respective first and second electronic components, and the package structure exposing a top side of the top of the thermally conductive band.

### BACKGROUND

Packaged electronic devices having multiple electronic components can benefit from topside heat removal for efficient thermal management and improved functionality. However, topside cooling can be difficult due to variations in thickness and height of components and semiconductor dies, leading to difficulties in molding operations to expose die backsides and/or tops of other electronic components outside a molded package structure.

### SUMMARY

In one aspect, an electronic device includes a thermally conductive band, a package structure, and first and second electronic components individually having lateral sides, a first side attached to a top side of a substrate, and an opposite second side, the thermally conductive band having a bottom extending on the second sides of the first and second electronic components, a top, and sidewalls individually extending between the bottom and the top of the thermally conductive band, where the top, the bottom, and the sidewalls of the thermally conductive band define an interior, and the package structure extending on the top side of the substrate, on the sidewalls and bottom of the thermally conductive band, and on the first side and the lateral sides of the respective first and second electronic components, and the package structure exposing a top side of the top of the thermally conductive band.

In another aspect, a system includes a circuit board, and an electronic device having a substrate with a conductive lead soldered to a conductive feature of the circuit board, first and second electronic components individually having lateral sides, a first side attached to a top side of a substrate, and an opposite second side, as well as a thermally conductive band having a bottom extending on the second sides of the first and second electronic components, a top, and sidewalls individually extending between the bottom and the top of the thermally conductive band, where the top, the bottom, and the sidewalls of the thermally conductive band define an interior, and a package structure extending on the top side of the substrate, on the sidewalls and bottom of the thermally conductive band, and on the first side and the lateral sides of the respective first and second electronic components, and the package structure exposing a top side of the top of the thermally conductive band.

In a further aspect, a method of fabricating an electronic device includes attaching bottom sides of first and second electronic components to a top side of a substrate, attaching a bottom of a thermally conductive band to top sides of the first and second electronic components, and forming a package structure on the top side of the substrate, on sidewalls and the bottom of the thermally conductive band, and on lateral sides of the first and second electronic components, the package structure exposing a top of the thermally conductive band.

### BRIEF DESCRIPTION OF THE DRAWINGS

FIG. 1 is a partial sectional side elevation view of an electronic device on a system circuit board and having a thermally conductive band on top sides of first and second electronic components and a top exposed outside a molded package structure taken along line 1-1 of FIG. 1A.

FIG. 1A is a top view of the electronic device of FIG. 1.

FIG. 1B is a partial sectional side elevation view of another electronic device with a thermally conductive band on top sides of first and second electronic components and a top with a cut exposed outside a molded package structure taken along line 1B-1B of FIG. 1C.

FIG. 1C is a top view of the electronic device of FIG. 1B.

FIG. 1D is a partial sectional side elevation view of another electronic device with a thermally conductive band on top sides of first and second electronic components and a top with a cut filled with solder exposed outside a molded package structure taken along line ID-1D of FIG. 1E.

FIG. 1E is a top view of the electronic device of FIG. 1D.

FIG. 1F is a partial sectional side elevation view of another electronic device with a thermally conductive band on top sides of first and second electronic components and a top with a cut exposed outside a molded package structure taken along line 1F-1F of FIG. 1G.

FIG. 1G is a top view of the electronic device of FIG. 1F.

FIG. 1H is a partial sectional side elevation view of another electronic device with heatsink soldered to a thermally conductive band on a system circuit board.

FIG. 1I is a partial sectional side elevation view of another electronic device on a system circuit board and having a thermally conductive band filled with thermally conductive material on top sides of first and second electronic components and a top exposed outside a molded package structure.

FIG. 2 is a flow diagram of a method of fabricating an electronic device.

FIGS. 3-10 show an electronic device undergoing fabrication processing according to various implementations of the method of FIG. 2.

FIG. 11 is a partial sectional side elevation view of another electronic device on a system circuit board and having a thermally conductive band on top sides of first and second electronic components, an additional die and passive components, and a top exposed outside a molded package structure taken along line 11-11 of FIG. 11A.

FIG. 11A is a top view of the electronic device of FIG. 11.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

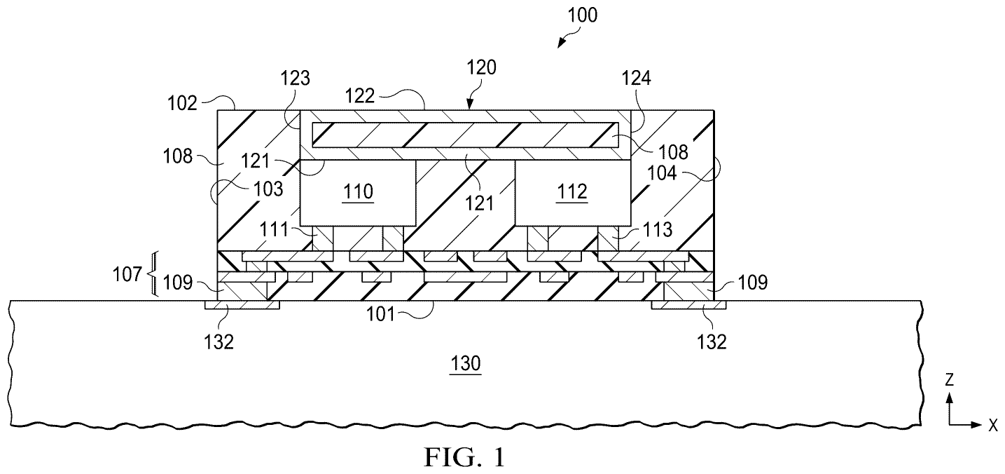

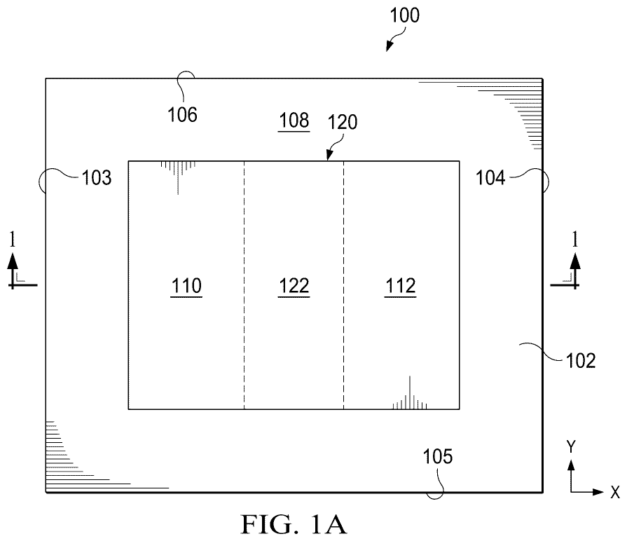

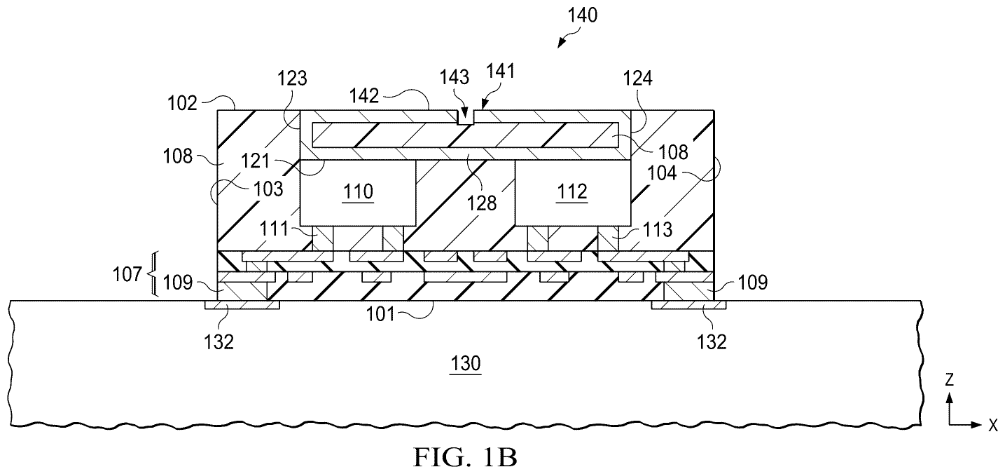

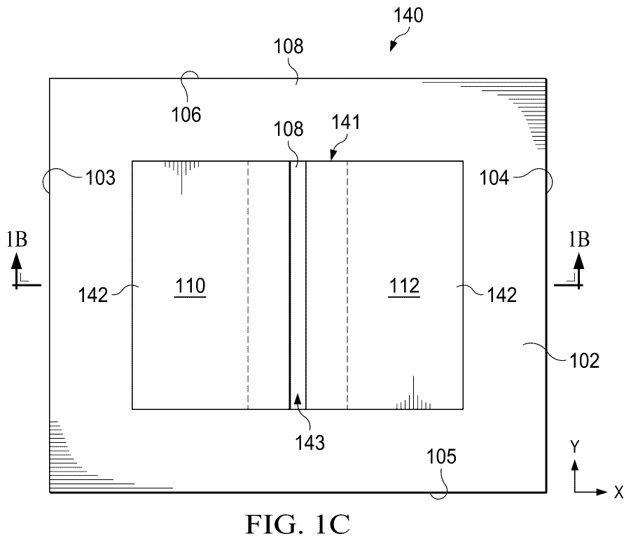

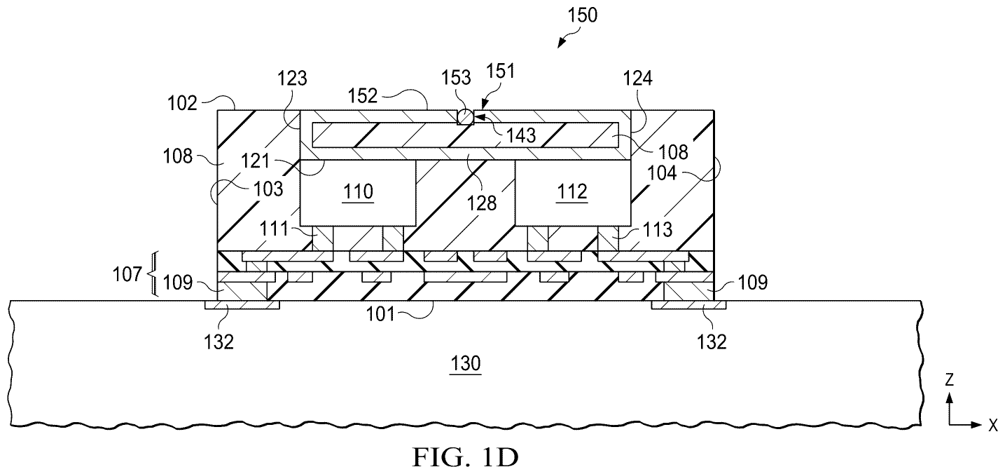

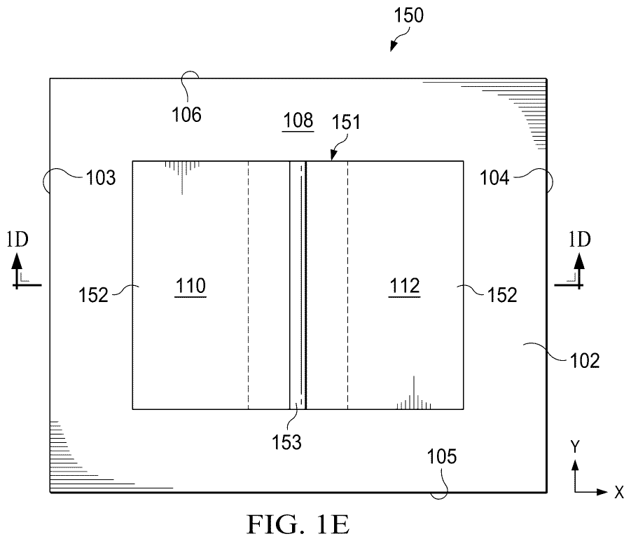

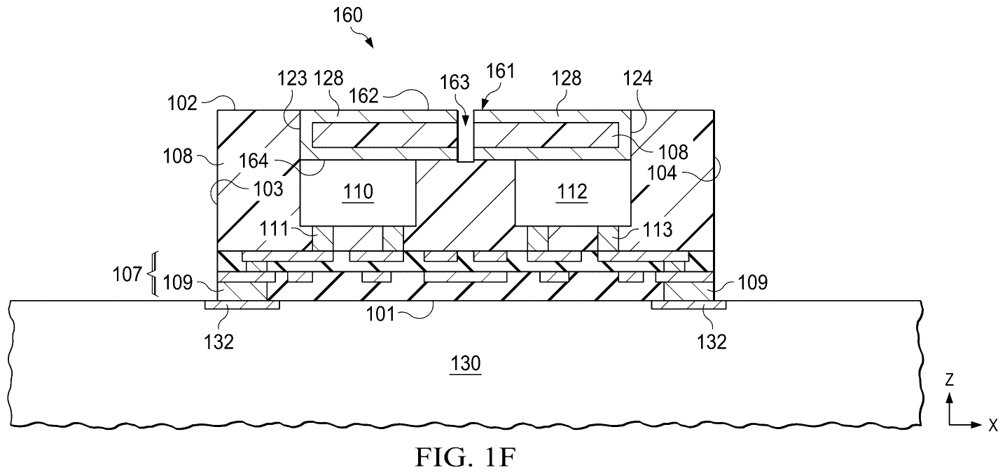

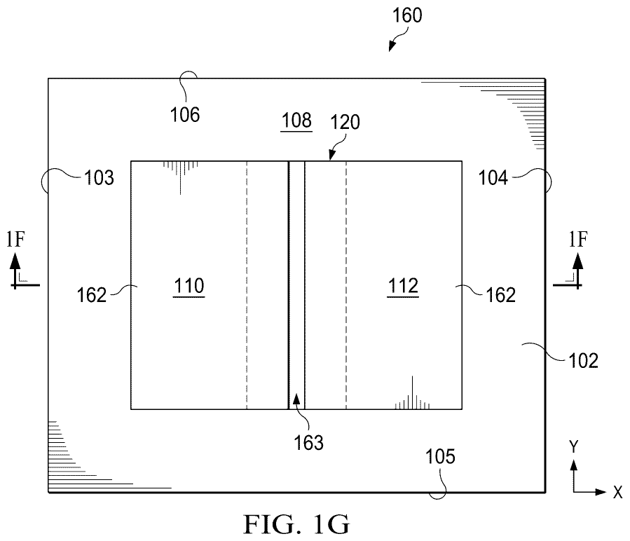

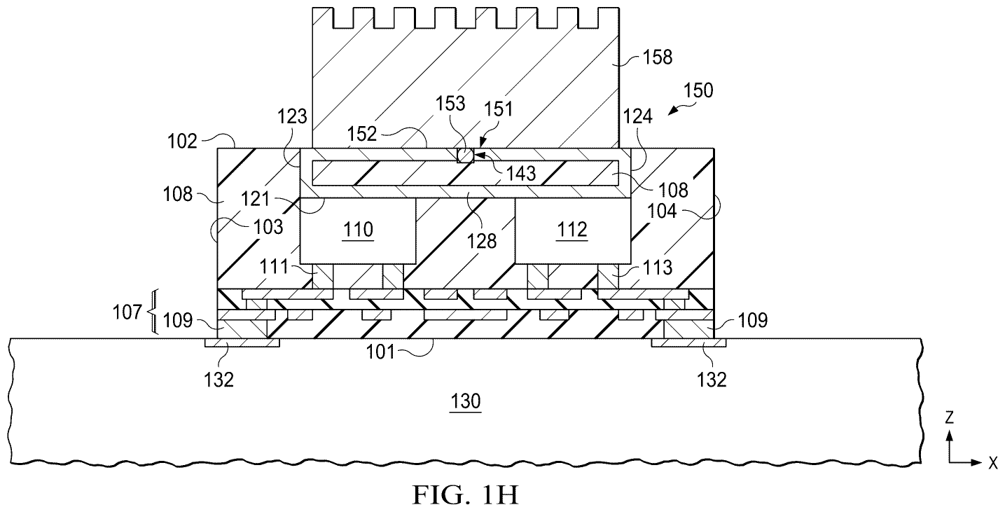

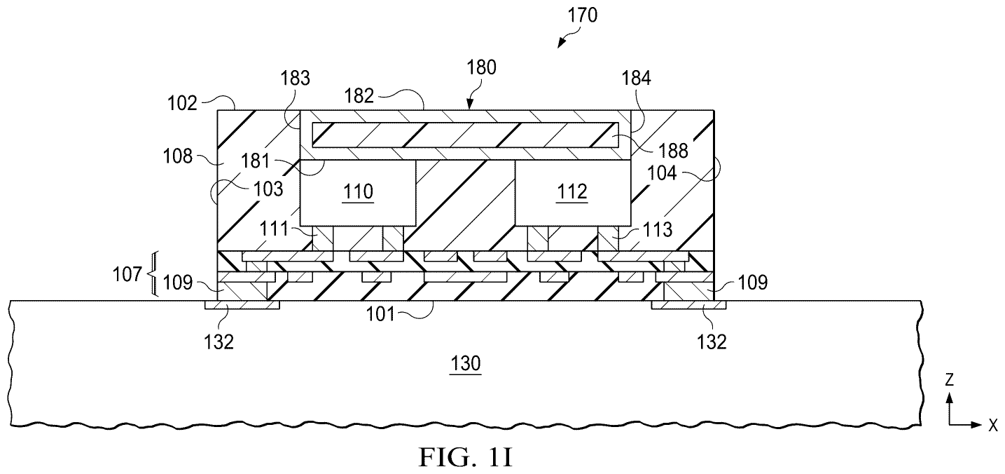

Referring initially to FIGS. 1 and 1A, FIG. 1 shows a side section view of an example electronic device 100 taken along line 1-1 of FIG. 1A and FIG. 1A shows a top view of the electronic device 100. The electronic device 100 includes top side cooling to facilitate thermal management for multiple electronic components integrated therein using a hollow thermally conductive band 120 that extends on top sides of two electronic components 110 and 112 and as a top side that is exposed outside a molded package structure to provide a thermal channel for heat removal that can be supplemented with installation of an external heat sink (e.g., FIG. 1H below).

The electronic device 100 and other example electronic devices are illustrated herein in an example position in a three-dimensional space with respective first, second, and third mutually orthogonal directions X (FIGS. 1 and 1A), Y (FIG. 1A), and Z (FIG. 1). The electronic device 100 includes opposite first and second (e.g., bottom and top) sides 101 and 102 (FIG. 1) that are spaced apart from one another along the third direction Z. The electronic device 100 also includes third and fourth sides 103 and 104 that are spaced apart from one another along the first direction Y, and fifth and sixth sides 105 and 106 (FIG. 1A) that are spaced apart from one another along the second direction Y.

As shown in FIG. 1, the electronic device 100 includes a substrate 107 along the first side 101 and a package structure 108 that extends from a top side of the substrate 107 to the second side 102. The substrate 107 in one example is a multilevel package substrate or a routable lead frame structure with conductive routing traces, conductive vias, and conductive metal leads 109 with bottom sides exposed along the first side 101. The substrate 107 also includes top side conductive metal features (e.g., metal pads) allowing soldering to bond wires and/or conductive metal terminals of attached electronic components such as by flip-chip soldering, surface mount component soldering, etc. The trace and via routings provide desired electrical connections from the components of the device 100 and the leads 109 of the substrate 107.

The electronic device 100 has multiple electronic components fully or partially enclosed by the package structure 108. The electronic components in one example include first and second semiconductor dies 110 and 112. In other examples, different types of electronic components can be included, such as semiconductor dies, passive or active surface mount components (e.g., resistors, capacitors, inductors, transformers, diodes, transistors, etc.) or combinations thereof. In the illustrated example, the first semiconductor die 110 has conductive metal terminals 111 (e.g., copper pillars or bumps) soldered to respective conductive features along the top side of the substrate 107. The second semiconductor die 112 has conductive metal terminals 113 (e.g., copper pillars or bumps) soldered to respective conductive features along the top side of the substrate 107.

The first electronic component 110 has lateral sides, a bottom or first side attached (e.g., by flip chip soldering of the terminals 111) to the top side of the substrate 107, and an opposite top or second side that is spaced apart from and faces the second side 102 of the electronic device 100 along the third direction Z. The second electronic component 112 has lateral sides, a bottom or first side attached (e.g., by flip chip soldering of the terminals 111) to the top side of the substrate 107, and an opposite top or second side that is spaced apart from and faces the second side 102 of the electronic device 100.

The semiconductor dies 110 and 112 are flip-chip soldered to the substrate 107 in the illustrated example. The front sides of the respective semiconductor dies 110 and 112 face the top side of the substrate 107, and die backsides face the top or first side 102 of the electronic device 100. In other implementations, other components including the backsides of one or more additional semiconductor dies can be attached to a lead frame or other substrate using adhesive, with bond wires forming electrical connections and/or lead frame routing traces can be used for interconnection. Various implementations can include any suitable combination of two or more electronic components attached to a substrate and having a thermally conductive band attached to approximately coplanar top sides of two of the components, and suitable electrical interconnections through substrate routing features and/or bond wires.

The electronic device 100 includes the thermally conductive band 120 on and contacting the top sides of the first and second electronic components 110 and 112 as best shown in FIG. 1. The thermally conductive band 120 can be any suitable thermally conductive material, which may also be electrically conductive, although not a requirement of all possible implementations. In addition, the thermally conductive band 120 is a hollow structure with an interior. In certain examples, the interior of the thermally conductive band 120 can be filled with thermally conductive material. In the illustrated example, the interior of the thermally conductive band 120 is fully or at least partially filled with mold compound material of the package structure 108, and the top 122 of the thermally conductive band 120 is exposed outside the package structure 108. In one example, the package structure 108 and the thermally conductive material in the interior of the thermally conductive band 120 include mold compound, such as epoxy molding compound (EMC). In another example, the thermally conductive band 120 can be filled with a different material, such as a pre-fill material provided in the interior of the thermally conductive band 120 prior to installation on the top sides of the electronic components 110 and 112 before molding, and such pre-fill material can be thermally conductive in certain implementations.

The thermally conductive band 120 has a bottom 121 and an opposite top 122 that are spaced apart from one another along the third direction Z, as well as lateral sidewalls 123 and 124 that are spaced apart from one another along the first direction X in the orientation of FIGS. 1 and 1A. The bottom 121 and the top 122 in one example extend in approximately parallel planes of the first and second directions (e.g., respective X-Y planes), although not a requirement of all possible implementations. The sidewalls 123 and 124 individually extend between the bottom 121 and the top 122. The top 122, the bottom 121, and the sidewalls 123 and 124 of the thermally conductive band 120 define an interior, such as a substantially rectangular interior channel with openings at opposite ends along the second direction Y in the illustrated example, although other shapes or profiles are possible in different implementations.

The lateral sidewalls 123 and 124 in this example extend in approximately parallel planes of the second and third directions (e.g., respective Y-Z planes), although not a requirement of all possible implementations. The sidewalls 123 and 124 individually extend between the bottom 121 and the top 122. The top 122, the bottom 121, and the sidewalls 123 and 124 of the thermally conductive band 120 define an interior, such as a substantially rectangular interior channel with openings at opposite ends along the second direction Y in the illustrated example, although other shapes or profiles are possible in different implementations.

In certain examples, the thermally conductive band 120 is installed (e.g., attached) on the top or second sides of the electronic components 110 and 112, and subsequent molding processing creates the package structure 108 that extends along the outer sides of the sidewalls 123 and under a portion of the bottom 121, as well as filling the interior of the thermally conductive band 120.

Manufacturing tolerance variations in the attachment and vertical height of the electronic components 110 and 112 can lead to the top or second sides of the electronic components 110 and 112 being slightly non-coplanar. In this situation, slight flexibility of the thermally conductive band 120 can allow slight compression thereof during molding operations to provide a top surface of the top 122 of the thermally conductive band 120 that may be slightly non-parallel with respect to the bottom 121 of the thermally conductive band 120 in the finished electronic device 100. Slightly nonparallel sidewalls 123 and 124 are also possible, for example, to accommodate slight relative movement during molding or other fabrication processing steps. The provision of the thermally conductive band 120 facilitates reliable provision of a thermal extraction surface along the top or second side 102 of the electronic device 100 even in the presence of these or other tolerance variations. Various implementations using a thermally conductive band 120 can advantageously mitigate or avoid mold flash and allow heat extraction through the top side 102 of the electronic device 100, whether alone or in further combination with an external heat sink (e.g., FIG. 1H below).

As shown in FIG. 1, the bottom 121 of the thermally conductive band 120 extends on respective portions of the second sides of the first and second electronic components 110 and 112. The thermally conductive band 120 can include any suitable thermally conductive material. In one example, the thermally conductive band 120 is or includes copper or other electrically conductive material, although not a requirement of all possible implementations. In another example, the thermally conductive band 120 includes an electrically nonconductive material.

In one example, the bottom 121 is attached to the second sides of the electronic components 110 and 112 using an adhesive. In one implementation, the adhesive between the second sides of the electronic components 110 and 112 and the bottom 121 of the thermally conductive band 120 is thermally conductive. In one example, the adhesive is electrically conductive, although not a requirement of all possible implementations. In another example, a thermally conductive and electrically nonconductive adhesive is used to attach the bottom 121 of the thermally conductive band 122 the second (e.g., top) sides of the electronic components 110 and 112.

The package structure 108 extends on a portion of the top side of the substrate 107 and may extend underneath the bottom sides of the electronic components 110 and 112 in the flip-chip attached implementation as shown in FIG. 1. The package structure 108 also extends on the sidewalls 123 and 124, and on the bottom 121 of the thermally conductive band 120. In addition, the package structure 108 exposes a top side of the top 122 of the thermally conductive band 120.

The electronic device 100 is shown in FIG. 1 installed on a system circuit board 130 having corresponding conductive features 132 on a top side thereof, with the conductive leads 109 of the substrate 107 to corresponding conductive features 132 of the circuit board 130. As shown in FIG. 1H below, a heatsink or other thermal management component can be attached to the top side of the top 122 of the thermally conductive band 120 to facilitate heat extraction from the electronic device 100 generally and in particular from the first and second electronic components 110 and 112 thereof.

FIGS. 1B and 1C show sectional side and top views of another example electronic device 140 having certain structures and features with similar numbers that are or can be generally as described above in connection with the electronic device 100 of FIGS. 1 and 1A unless described differently hereinafter. The electronic device 140 has electronic components 110 and 112 as described above as well as a thermally conductive band 141 on the top sides of the first and second electronic components 110 and 112. The thermally conductive band 141 includes a bottom 121 and sidewalls 123 and 124 and is generally the same as the thermally conductive band 120 described above. In this example, the thermally conductive band 141 has a top 142 with a cut 143 that separates first and second portions of the top 142. In the illustrated example, the top 142, the bottom 121 and the sidewalls 123 and 124 define an interior that is filled in one implementation with mold compound material of the package structure 108, although another implementation can include a different material in the interior of the thermally conductive band 141. As shown in FIG. IC, the cut exposes the material 108 along the length of the thermally conductive band 141 along the second direction Y. In other examples, the cut 143 need not extend to either or both of the edges of the top 142.

FIGS. 1D and 1E illustrate respective sectional side and top views of another example electronic device 150 with similarly numbered structures and features as described above unless described differently hereinafter. The electronic device 150 includes electronic components 110 and 112 as described above along with a thermally conductive band 151 on the top sides of the first and second electronic components 110 and 112 and having an interior filled with molding compound of the package structure 108. The thermally conductive band 151 in this example includes a top 152 with a cut 143 as described above in connection with FIGS. 1B and 1C, along with a bottom 121 and sidewalls 123 and 124 as previously described. In addition, the electronic device 150 includes solder 153 in the cut 143 in the top 152 of thermally conductive band 151. The solder 153 in one example extends into the cut 143 and onto a portion of the mold compound material of the package structure 108, although not a requirement of all possible implementations. The solder 153 can advantageously facilitate subsequent attachment of a heatsink (e.g., FIG. 1H) to help extract heat from the electronic components 110 and 112 of the electronic device 150.

FIGS. 1F and 1G provide sectional side and top views of yet another electronic device 160 having similarly numbered structures and features as described above unless described differently hereinafter. The example electronic device 160 includes electronic components 110 and 112 as described above along with a thermally conductive band 161 on the top sides of the first and second electronic components 110 and 112 and having an interior filled with molding compound of the package structure 108. The thermally conductive band 161 in this example includes a top 162 with a cut 163 that extends through the top 162 and separates first and second portions of the top 162, for example as described above in connection with FIGS. 1B and 1C. The thermally conductive band 161 in this example also has sidewalls 123 and 124 as previously described, as well as a bottom 164. The cut 163 in this example extends through the mold compound material 108 in the interior of the thermally conductive band 161. In addition, the cut 163 extends through the bottom 164 to separate first and second portions of the bottom 164. The cut 163 in this example separates left and right halves of the thermally conductive band 161, which can advantageously mitigate or prevent short circuits or parasitics between the first and second electronic components 110 and 112.

FIG. 1H shows a partial sectional side view of another system implementation of electronic device 150 as described above in connection with FIGS. 1D and 1E. The system in this example includes a heatsink or heat spreader 158 installed on at least a portion of the top side of the top 152 of the thermally conductive band 151. In one example, the heatsink 158 has a lower or bottom side or surface that is at least partially soldered to the top side of the top 152 of the thermally conductive band 151 by reflow of the solder 153 previously formed at least partially within the cut 143 in the top 152. In one example, the heatsink 158 is soldered to the electronic device 150 after the device 150 is soldered to the circuit board 130. In another example, the heatsink 158 can be soldered to the top side of the top 152 of the thermally conductive band 150 prior to attachment of the electronic device 150 to the circuit board 130.

FIG. 1I shows a sectional side view of another electronic device 170 on a system circuit board 130. The electronic device 170 includes a thermally conductive band 180 similar in some respects to the thermally conductive band 120 as described above, with a bottom 181 on the top sides of the electronic components 110 and 112 (e.g., similar to the bottom 121 described above), as well as sidewalls 183 and 184 similar to the sidewalls 123 and 124 described above, and a top 182 similar to the top 122 described above. The bottom of 181, the top 182, and the sidewalls 183 and 184 define an interior of the thermally conductive band 180. In this example, however, the interior of the thermally conductive band 180 is fully or partially filled with thermally conductive material 188. The fill material 188 and the thermally conductive band 180 provide a thermal channel to extract heat from the electronic device 170 and in particular the electronic components 110 and 112 thereof and may have better thermal conductivity compared to a thermally conductive band filled with the molding compound material of the package structure 108 as in the above examples. In one implementation, the thermally conductive band 180 is a hollow structure with the interior opened at opposite ends (e.g., along a second direction into and out of the page in FIG. 1I).

In one example, the interior of the thermally conductive band 180 can be filled with the material 188 before installation on the electronic components 110 and 112 (e.g., a pre-filled thermally conductive band 180 fabricated in a separate process). In one example, a long strip of preformed thermally conductive material 188 can be fabricated as an elongated rectangular structure (not shown), and a thermally conductive band material (e.g., copper, aluminum, etc.) can be wrapped around the thermally conductive rectangle and then cut to length for use in packaging operations to be attached (e.g., by thermally conductive adhesive, solder paste, or other suitable thermally conductive materials) to the top sides of two or more electronic components 110 and 112 during packaging of the electronic device 150. In other implementations, the thermally conductive band (e.g., 120, 141, 151, 161, 180) can have closed interiors, for example, pre-filled with thermally conductive material or other materials, with the band material (e.g., copper) extending along six sides of the band structure, and the band material can (but need not) form a seal with respect to the interior.

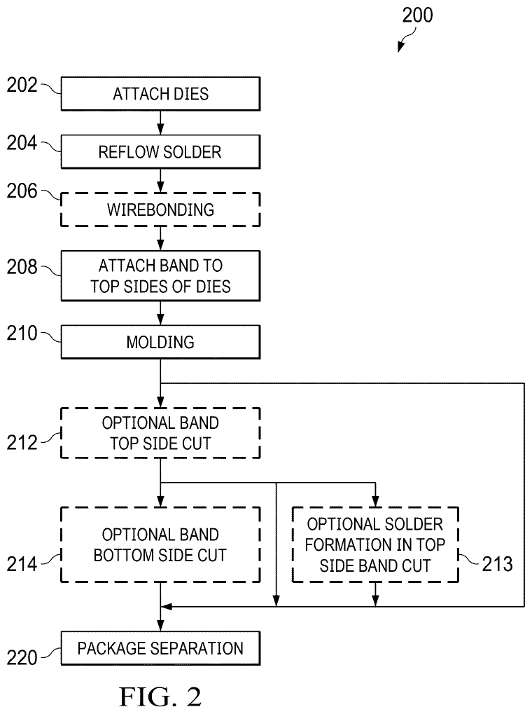

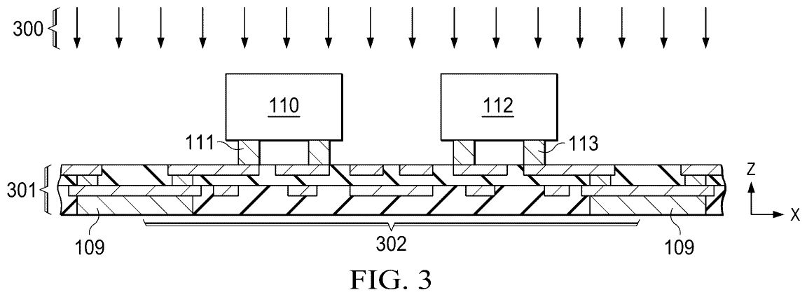

Referring also to FIGS. 2-10, FIG. 2 shows a method 200 of fabricating an electronic device, and FIGS. 3-10 show the example electronic device 100 and variants thereof undergoing fabrication processing according to various example implementations of the method 200. The method 200 begins at 202 with electronic component attachment, such as die attach processing, passive or other component attachment. The attachment at 202 can include dispensing or screen printing solder paste and/or conductive or nonconductive die attach adhesive to a starting lead frame or other substrate, for example, in a panel array structure having rows and columns of individual unit areas. FIG. 3 shows one example, in which a die attach process 300 is performed using a starting substrate panel array 301 with multiple unit areas 302, one of which is shown. In one implementation, solder paste is formed (e.g., by printing, silk screening, dispensing, or other suitable technique) in select portions on certain conductive features of a top side of the substrate 301. The electronic components 110 and 112 (e.g., semiconductor dies) are positioned with the conductive terminals 111 and 113 on respective conductive features in each unit area 302 of the substrate 301, for example, using automated pick and place equipment (not shown). The illustrated example is a flip-chip die attach process, which can be used alone or in combination with other component attachment techniques and equipment.

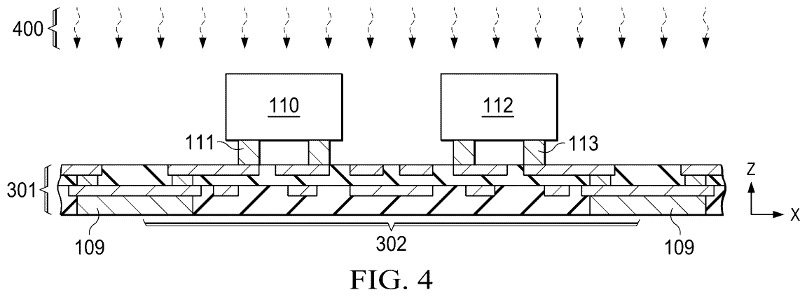

The method 200 continues at 204 in FIG. 2 with solder reflow processing. FIG. 4 shows one example, in which a thermal process 400 is performed that reflows the solder paste to form solder connections between the semiconductor die copper pillar terminals 111, 113 and the corresponding conductive metal features on the top side of the substrate panel array 301. The flip-chip die attach processing at 202 and 204 can also include similar processing for attaching surface mount components (e.g., passive resistors, capacitors, inductors, transformers, active components such as transistors, etc.) with terminals positioned on solder paste previously applied to corresponding conductive metal features of the substrate panel array 301, followed by thermal reflow at 204 to form corresponding solder connections of the attached components to the multilevel package substrate panel array 301.

Another implementation can also include other die or component attachment processing, for example, after or instead of any included flip-chip solder reflow processing at 204. For example, one implementation can include forming die attach adhesive (not shown, e.g., by printing, silk screening, dispensing, etc.) on one or more conductive or non-conductive features of the substrate panel array 301, followed by automated pick and place attachment of die back sides and/or other electronic components (not shown) on the die attach adhesive, followed by any beneficial adhesive curing process to form mechanical, structural attachment of the components to the substrate panel array 301.

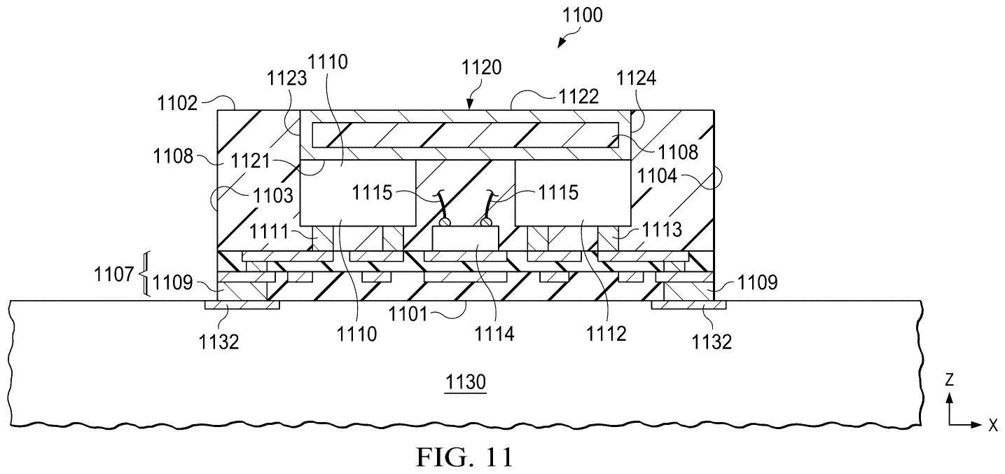

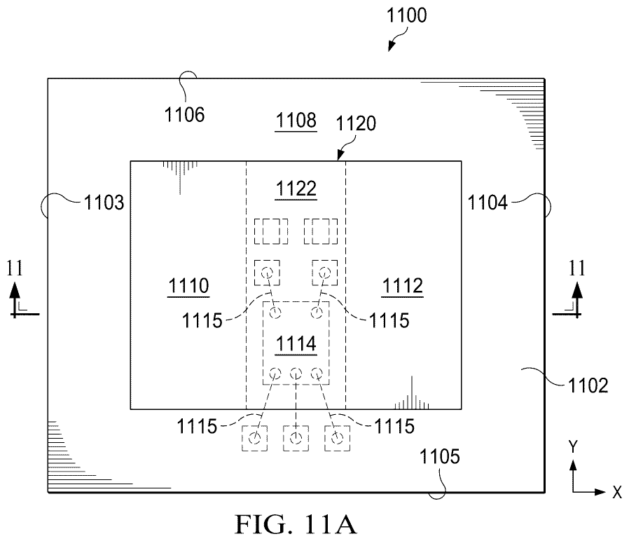

In one implementation, the method 200 includes optional wire bonding at 206 in FIG. 2, for example, to form bond wires (e.g., FIGS. 11 and 11A below) that make any desired electrical connections between electronic components and/or conductive features in each unit area 302 of the substrate panel array 301 in each unit area 302. In other examples, such as strictly flip-chip and SMT implementations, the wirebonding at 206 can be omitted.

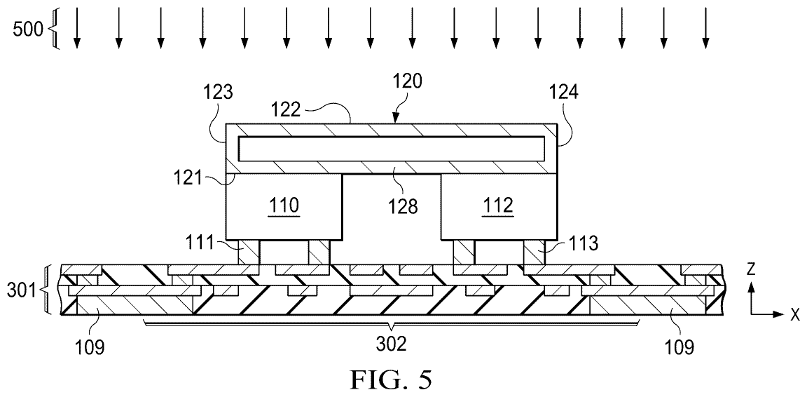

The method 200 continues at 208 in FIG. 2 with thermally conductive band attachment. FIG. 5 shows one example, in which a band attachment process 500 is performed that attaches the thermally conductive band 120 to the top sides of the electronic components 110 and 112. In one example, the attachment process 500 includes forming a thermally conductive adhesive (not shown) on the top sides of the electronic components 110 and 112, for example, by dispensing, printing, silk screening, or other suitable process and equipment. The thermally conductive band 120 (e.g., whether initially hollow or including any pre-fill material in the interior thereof) is positioned with the bottom side of the bottom 121 engaging at least a portion of the top sides of the electronic components 110 and 112, for example, using automated pick and place equipment (not shown). The band attachment in one example is repeated for each unit area 302 of the substrate panel array structure 301.

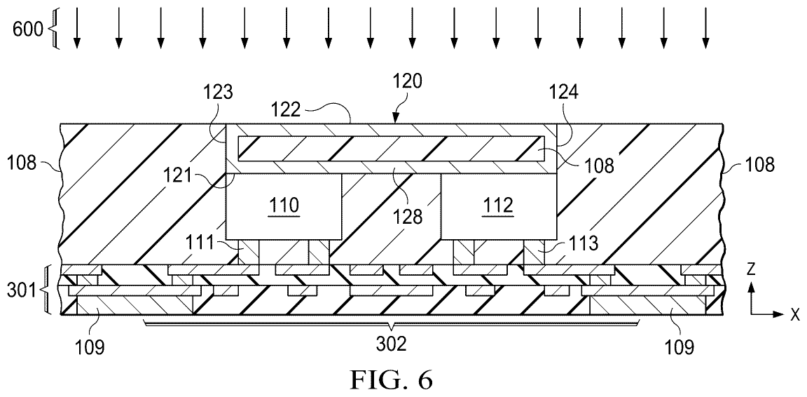

At 210 in FIG. 2, the method 200 continues with package structure formation. FIG. 6 shows one example, in which a molding process 600 is performed using a mold (not shown) that has a cavity with a top surface that engages the top side of the top 122 of the thermally conductive band 120, and the top mold surface in one example is generally planar and extends across the illustrated unit area 302 and into scribe regions between adjacent unit areas 302. In one implementation, a single mold cavity can be used to create a molded package structure 108 in each unit area 302, which are subsequently separated during package separation processing (e.g., at 220 in FIG. 2). In other implementations, the individual mold cavities can be used for each unit area 302 or groups of fewer than all unit areas 302 can be included within a shared mold cavity (not shown). The molding process 600 forms the molded package structure 108, which extends on the top side of the substrate 301, on sidewalls the sidewalls 123 and 124 and the bottom 121 of the thermally conductive band 120, and the molded package structure 108 extends on lateral sides of the first and second electronic components 110 and 112. In one example, the molding process 600 forms mold compound 108 or other thermally conductive material inside the interior of the thermally conductive band 120. In another implementation, a prefilled thermally conductive band 120 can be used, and the molding process 600 does not form mold compound material inside the interior of the thermally conductive band 120.

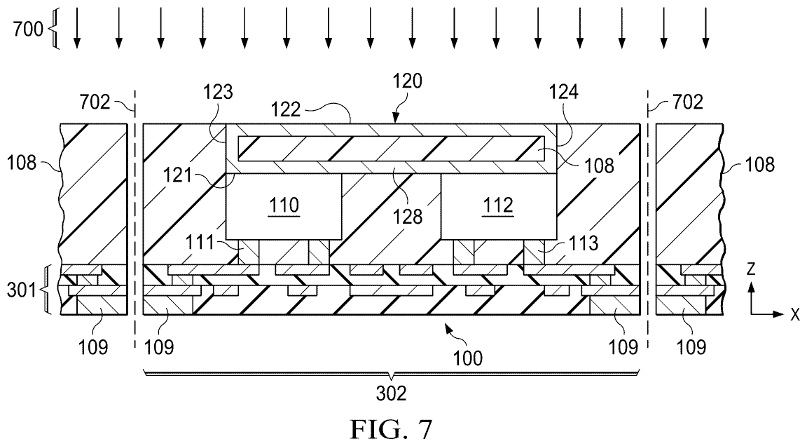

In one implementation, the method 200 proceeds with package separation at 220 in FIG. 2. FIG. 7 shows one example, in which a package separation process 700 is performed that separates individual packaged electronic devices 100 from the starting substrate panel array structure 301 along lines 702 in scribe streets between adjacent rows and columns of unit areas of the starting array structure. In one implementation, the separation process 700 includes saw cutting. In other implementations, one or more different separation processes can be used, for example, saw cutting, laser cutting, chemical etching, or combinations thereof, etc. This implementation of the method 200 provides the example electronic device 100 as described above in connection with FIGS. 1 and 1A.

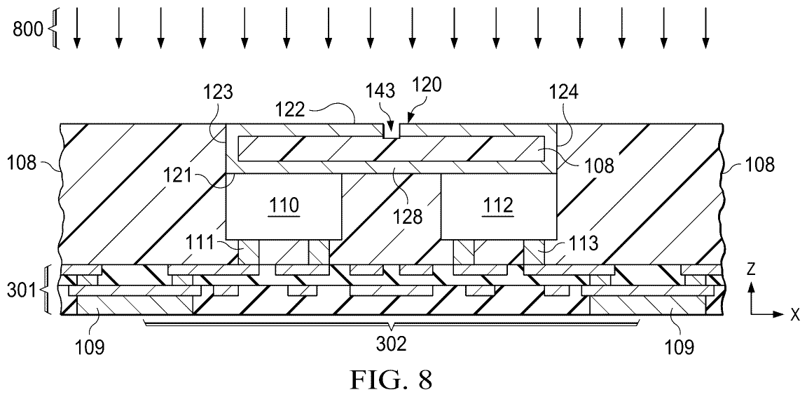

In another implementation, the method 200 continues with band top side cutting at 212 in FIG. 2 after molding at 210. FIG. 8 shows one example, in which a saw cutting process 800 is performed that forms a cut 143 between first and second portions of the top 122 of the thermally conductive band 120. In the example of FIG. 8, the cutting process 800 forms the cut 143 that extends through the top 122 of the thermally conductive band 120 and exposes a portion of the mold compound material 108 within the interior of the thermally conductive band 120. In one example, the method 200 in FIG. 2 proceeds to package separation at 220 (after band top side cutting at 212) to provide individual packaged electronic devices 140 as described above in connection with FIGS. 1B and 1C.

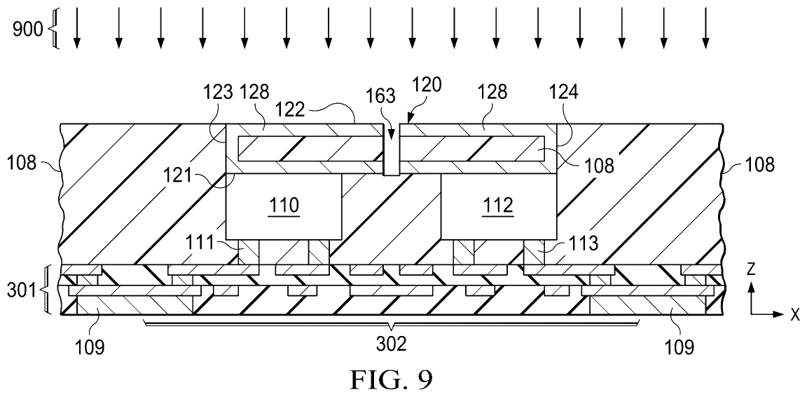

The method 200 in FIG. 2 in one example continues at 214 with optional band bottom side cutting. FIG. 9 shows one example, in which a cutting process 900 is performed that extends the cut through the interior and through the bottom 121 of the thermally conductive band 120. In one implementation, the cutting process 900 can be a continuation of the earlier cutting process 800 that form the cut 143 through the top 122 of the thermally conductive band 120, although separate processes can be used in other implementations. In this example, the method 200 of FIG. 2 proceeds (after band bottom side cutting at 214) to package separation at 220 as described above in connection with FIG. 7, for example, to provide individual packaged electronic devices 160 as described above in connection with FIGS. 1F and 1G.

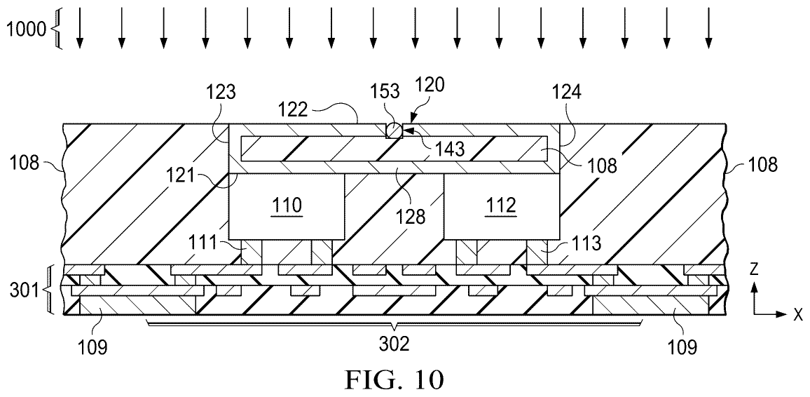

In another variant implementation, the method 200 in FIG. 2 continues with optional solder formation in the top side band cut at 213 in FIG. 2 (e.g., after band top side cutting at 212). FIG. 10 shows one example, in which a solder formation process 1000 is performed that forms the solder 153 in the cut 143 previously formed at 212. In one example, the solder formation process 1000 can include forming solder paste in or around the cut 143 (e.g., by printing, silk screening, dispensing, etc.), and the process 1000 can include post formation solder reflow (e.g., thermal) processing to form the solder 153 within the cut 143, where the solder 153 can extend slightly beyond the top side as shown in the example of FIG. 10. In this example, the method 200 then proceeds to package separation at 220 in FIG. 2, for example, to provide individual packaged electronic devices 150 as described above in connection with FIGS. 1D and 1E.

FIGS. 11 and 11A show respective side section and top views of another example electronic device 1100 in a system. In one implementation, the electronic device 1100 and the system of FIGS. 11 and 11A includes structure and features 1101-1113, 1120-1124, 1130 and 1132 that are the same as the structure and features 101-113, 120-124, 130 and 132 of the electronic device 100 as described above in association with FIGS. 1 and 1A. In addition, the electronic device 1100 in FIGS. 11 and 11A has further electronic components including an additional semiconductor die 1114 with a backside (e.g., bottom side) attached to a top side of the substrate 1107 using die attach adhesive (e.g., conductive or non-conductive), as well as other passive surface mount components (FIG. 11A) attached to the top side of the substrate 1107. In addition, the electronic device 1100 includes bond wires 1115 forming electrical circuit interconnections between the semiconductor die 1114 and other conductive features along the top side of the substrate 1107, with surface mount component connections being made by corresponding conductive routing features within the substrate 1107. The bond wires 1115 in this example are in addition to the flip-chip electrical connections made with respect to the terminals 1111 and 1113 of the corresponding first and second semiconductor dies 1110 and 1112.

Described examples provide thermal management solutions that facilitate heat transfer by integration of a copper or other thermally conductive band (e.g., 120) attached to the top sides of one or more electronic components in the package structure (e.g., 108) with a top side of the conductive band exposed outside the top of the package structure. Described examples facilitate heat removal from the electronic device and components thereof alone or in combination with an installed heat sink (e.g., FIG. 1H), and integration of the thermally conductive band within the electronic device does not require any new or modified packaging processing or equipment, for example, using well-developed surface mount component attachment techniques. Moreover, the thermally conductive band (e.g., 120) can accommodate manufacturing tolerances, for example, with respect to semiconductor die thicknesses and other dimensional variations associated with flip-chip die attachment processes, wafer processing, etc., to mitigate or avoid over-molding or mold flash while facilitating thermal management of electronic devices having multiple electronic components, such as multichip module (MMC) devices. The described solutions provide utility in changing device designs, for example, to help introduce new components to meet additional functional requirements of a given electronic device design rather than revising die design thicknesses.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a first electronic component having lateral sides, a first side attached to a top side of a substrate, and an opposite second side;
a second electronic component having lateral sides, a first side attached to the top side of the substrate, and an opposite second side;
a thermally conductive band having a bottom extending on the second sides of the first and second electronic components, a top, and sidewalls individually extending between the bottom and the top of the thermally conductive band, the top, the bottom, and the sidewalls of the thermally conductive band defining an interior; and
a package structure extending on the top side of the substrate, on the sidewalls and bottom of the thermally conductive band, and on the first side and the lateral sides of the respective first and second electronic components, and the package structure exposing a top side of the top of the thermally conductive band.

2. The electronic device of claim 1, wherein the first electronic component is a first semiconductor die, and the second electronic component is a second semiconductor die.

3. The electronic device of claim 1, wherein the package structure extends in the interior of the thermally conductive band.

4. The electronic device of claim 1, wherein the thermally conductive band includes a cut separating first and second portions of the top of the thermally conductive band.

5. The electronic device of claim 4, further comprising solder in the cut in the thermally conductive band.

6. The electronic device of claim 4, wherein the cut extends through the bottom of the thermally conductive band.

7. The electronic device of claim 1, wherein the first electronic component is a first semiconductor die flip-chip soldered to conductive features of the substrate, and the second electronic component is a second semiconductor die flip-chip soldered to other conductive features of the substrate.

8. The electronic device of claim 1, wherein the thermally conductive band includes copper.

9. The electronic device of claim 1, comprising a thermally conductive material in the interior of the thermally conductive band.

10. The electronic device of claim 9, wherein the package structure and the thermally conductive material in the interior of the thermally conductive band include mold compound.

11. The electronic device of claim 1, wherein the package structure includes mold compound.

12. A system, comprising:
a circuit board having a conductive feature; and
an electronic device, including:
a substrate with a conductive lead soldered to the conductive feature of the circuit board;
a first electronic component having lateral sides, a first side attached to a top side of the substrate, and an opposite second side;
a second electronic component having lateral sides, a first side attached to the top side of the substrate, and an opposite second side;
a thermally conductive band having a bottom extending on the second sides of the first and second electronic components, a top, and sidewalls individually extending between the bottom and the top of the thermally conductive band, the top, the bottom, and the sidewalls of the thermally conductive band define an interior; and
a package structure extending on the top side of the substrate, on the sidewalls and bottom of the thermally conductive band, and on the first side and the lateral sides of the respective first and second electronic components, and the package structure exposing a top side of the top of the thermally conductive band.

13. The system of claim 12, wherein the package structure extends in the interior of the thermally conductive band.

14. The system of claim 12, wherein the thermally conductive band includes a cut separating first and second portions of the top of the thermally conductive band.

15. A method of fabricating an electronic device, the method comprising:
attaching bottom sides of first and second electronic components to a top side of a substrate;
attaching a bottom of a thermally conductive band to top sides of the first and second electronic components; and
forming a package structure on the top side of the substrate, on sidewalls and the bottom of the thermally conductive band, and on lateral sides of the first and second electronic components, the package structure exposing a top of the thermally conductive band.

16. The method of claim 15, wherein forming the package structure includes performing a molding process (600) that forms mold compound on the top side of the substrate, on the sidewalls and the bottom of the thermally conductive band, inside an interior of the thermally conductive band, and on the lateral sides of the first and second electronic components.

17. The method of claim 15, further comprising forming a thermally conductive material in an interior of the thermally conductive band.

18. The method of claim 15, further comprising forming a cut between first and second portions of the top of the thermally conductive band.

19. The method of claim 18, comprising extending the cut through the bottom of the thermally conductive band.

20. The method of claim 18. further comprising forming solder in the cut.
